(19) United States
(12) Patent Application Publication
(10) Pub. No.: US 2026/0140148 A1
(43) Pub. Date: May 21, 2026

(54) CURRENT SENSOR

(71) Applicant: Kohshin Electric Corporation, Kasaoka-shi, Okayama (JP)

(72) Inventors: Takehisa SATO, Kasaoka-shi, Okayama (JP); Yuki KUBO, Kasaoka-shi, Okayama (JP)

(21) Appl. No.: 19/121,468

(22) PCT Filed: Oct. 20, 2023
(86) PCT No.: PCT/JP2023/038105

§ 371 Date: Apr. 16, 2025

(30) Foreign Application Priority Data
Oct. 21, 2022 (JP) 2022-169370

(51) Int. Cl. G01R 15/20; G01R 19/00

(52) U.S. Cl. CPC G01R 15/207; G01R 19/0092; G01R 15/202

(57) ABSTRACT

A conductor of a current sensor detects electric current and has first and second current paths branching at a through-slit; substantially U-shaped first and second magnetic cores; and a pair of magnetoelectric conversion elements placed opposite each other across the through-slit. Magnetic flux density in a specified direction of a magnetically-sensitive axis of a magnetic flux generated from the electric current is detected, and output. The first magnetic core surrounds a periphery of the first current path excluding a portion which forms a sidewall on one side of the through-slit; and the second magnetic core surrounds a periphery of the second current path excluding a portion which forms a sidewall on the other side of the through-slit. The first and second magnetic cores are placed in a position with their two end faces facing opposite each other; and a core gap is formed between the two opposed end faces.

### TECHNICAL FIELD

The present invention relates to a current sensor using magnetoelectric conversion elements.

### BACKGROUND ART

Regarding a current sensor used for, for example, a conventional motor drive inverter, there is known a current sensor of a differential detection type that cancels any influence of a surrounding external magnetic field by placing two magnetoelectric conversion elements so that a current path, through which an electric current to be detected flows, is located between the magnetoelectric conversion elements, and performing differential calculation of a detection signal, thereby precisely detecting the electric current to be detected.

For example, PTL 1 shows a current sensor characterized in that when the electric current to be detected is applied to a conductor, which has one or more through-hole parts (through-slits) and is formed in a linear shape, the current sensor detects a magnetic field gradient (a magnetic flux density amount according to the positions of magnetoelectric conversion elements) by using a differential field measurement apparatus (the magnetoelectric conversion elements and a differential calculation unit), thereby detecting the amount of electric current applied to the conductor.

Moreover, PTL 2 shows a current sensor with a conductor, which has a gap (through-slit) and two current paths located symmetrically with respect to the through-slit, and whose cross-section has a rectangular shape, wherein a pair of magnetoelectric conversion elements are located outside the through-slit gap and with the conductor located between the magnetoelectric conversion elements; the current sensor cancels any influence of a surrounding magnetic field caused by magnetic fluxes, which are generated by applying the electric current to be detected to the conductor, by performing the differential calculation of the detection signal, thereby detecting the electric current to be detected.

### CITATION LIST

### Patent Literature

PTL 1: Japanese Unexamined Patent Application Publication (Translation of PCT Application) No. 2002-523751

PTL 2: Japanese Patent No. 6144597

### SUMMARY OF THE INVENTION

### Problems to be Solved by the Invention

However, regarding any one of the patent literature, the magnetoelectric conversion elements directly detect the magnetic fluxes generated by applying the electric current to be detected, so that the magnetic flux density amount which can be detected by the magnetoelectric conversion element is very small and the magnetoelectric conversion elements with high detection sensitivity such as magnetoresistive elements are used to output an output signal(s) according to the detected magnetic flux density amount; and since the detected magnetic flux density amount is very small, the output signal(s) which is output is small and it is thereby necessary to increase an amplification factor for the output signal(s).

If the amplification factor for the output signal(s) is increased, even a slight change in the magnetic flux density amount would have significant influence. So, even if the current sensor has an external magnetic field cancellation function by means of the differential calculation under the external magnetic field environment of the current sensor, it will detect a slight amount of the magnetic flux density amount, which will have significant influence.

In light of the above-described problem, the present invention proposes a current sensor capable of increasing the magnetic flux density to be detected by the magnetoelectric conversion elements and reducing the amplification factor for the output signal(s) to be output from the magnetoelectric conversion elements.

### Means to Solve the Problems

A current sensor according to the present invention includes: a conductor to which an electric current to be detected is applied, and which has a first current path and a second current path that branch at a through-slit; substantially U-shaped first and second magnetic cores, each of which has two end faces; and a pair of magnetoelectric conversion elements that are placed opposite each other across the through-slit, respectively detect magnetic flux density in a specified direction of a magnetically-sensitive axis of a magnetic flux generated from the electric current to be detected, and output an output signal according to the magnetic flux density, wherein the first magnetic core is placed to surround at least a part of a periphery of the first current path excluding a portion which forms a sidewall on one side of the through-slit; wherein the second magnetic core is placed to surround at least a part of a periphery of the second current path excluding a portion which forms a sidewall on the other side of the through-slit; wherein each of the first and second magnetic cores is placed in a position with their two end faces facing opposite each other; and wherein a core gap is formed between the two opposed end faces.

### Advantageous Effects of the Invention

According to the present invention, there is provided the current sensor capable of increasing the magnetic flux density to be detected by the magnetoelectric conversion elements and reducing the amplification factor for the output signal(s) which is output from the magnetoelectric conversion elements.

### BRIEF DESCRIPTION OF DRAWINGS

FIG. 1 is schematic views of a current sensor according to Embodiment 1 of the present invention; FIG. 1(a) is a perspective view of the current sensor, FIG. 1(b) is a planar view of the current sensor, and FIG. 1(c) is a sectional view.

FIG. 2 is a diagram illustrating a configuration example in which the position of a through-slit of the current sensor illustrated in FIG. 1 and a cross-sectional area of current paths are changed.

FIG. 3 is sectional views illustrating configuration examples in which magnetic cores of the current sensor illustrated in FIG. 1 are changed.

FIG. 4 is schematic views illustrating magnetic flux paths when an electric current to be detected is applied to the current sensor according to Embodiment 1 of the present invention; FIG. 4(a) is a diagram illustrating magnetic flux paths which pass through magnetic cores and a core gap and FIG. 4(b) is a diagram illustrating magnetic flux paths whose magnetism does not converge at the magnetic cores.

FIG. 5 is diagrams illustrating configuration examples of arrangement changes of the through-slit, the core gap, and the magnetoelectric conversion elements of the current sensor according to Embodiment 1 of the present invention.

FIG. 6 is a table showing analysis values of a magnetic flux density change rate at respective frequencies regarding the configuration examples (a) to (d) indicated in FIG. 5.

FIG. 7 is sectional views illustrating positional change examples of the through-slit and the magnetoelectric conversion elements of the current sensor illustrated in FIG. 1.

FIG. 8 is perspective views of a current sensor having a conductor according to aspects different from those of the conductor for the current sensor according to Embodiment 1 of the present invention.

### DESCRIPTION OF EMBODIMENTS

### Embodiment 1

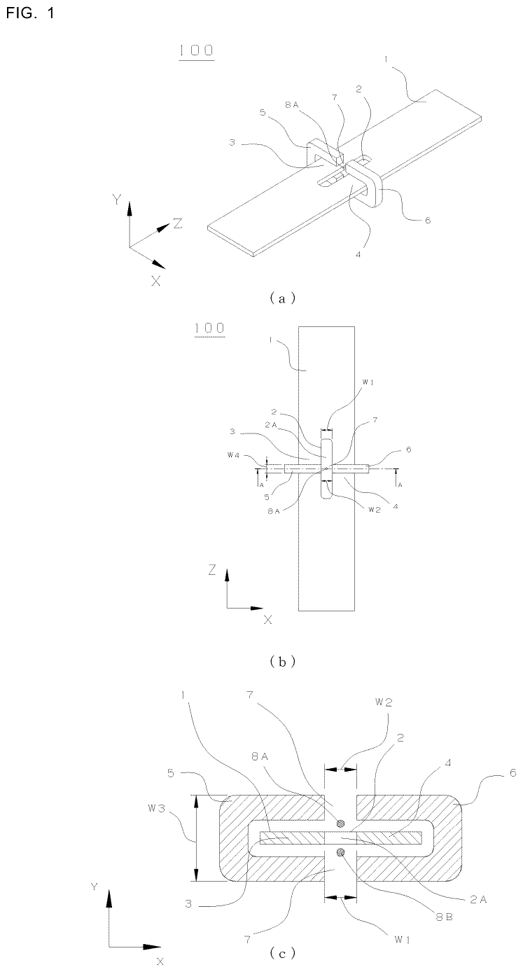

FIG. 1 is schematic views of a current sensor 100 according to Embodiment 1 of the present invention. FIG. 1(a) is a perspective view of the current sensor 100 according to Embodiment 1, FIG. 1(b) is a planar view of the current sensor 100 according to Embodiment 1, and FIG. 1(c) is a sectional view taken along line A-A in FIG. 1(b). Moreover, unless particularly explained in the present invention, a width direction of a conductor along which an electric current to be detected flows is defined as an X-direction, a thickness direction of the conductor is defined as a Y-direction, an extending direction of the conductor is defined as a Z-direction, directions indicated with arrows in the drawing are defined as +(positive) directions, and the respective directions regarding Embodiment 1 are defined in the same manner.

Referring to FIG. 1, the current sensor 100 according to Embodiment 1 of the present invention includes: a conductor 1 to which an electric current to be detected is applied, and which has a through-slit 2 whose X-directional width dimension is a width length W1; a current path 3 and a current path 4 which are formed by the through-slit 2; a U-shaped magnetic core 5 which is placed along the periphery of the current path 3 to surround the periphery excluding a portion forming a sidewall on one side of the through-slit 2, and which has a height dimension W3 in the Y-direction and a thickness dimension W4 in the Z-direction; a U-shaped magnetic core 6 which has the same shape as that of the magnetic core 5 and which is placed along the periphery of the current path 4 to surround the periphery excluding a portion forming a sidewall on the other side of the through-slit 2; two core gaps 7 which are formed of gaps between the opposed end faces of the magnetic core 5 and the magnetic core 6 and whose X-directional width is a width length W2; and a magnetoelectric conversion element 8A and a magnetoelectric conversion element 8B which are detection elements for detecting magnetic fluxes, wherein the core gap 7 is formed as illustrated in FIG. 1(c) so that the width length W1 of the through-slit 2 overlaps with the width length W2 of the core gap 7; and the magnetoelectric conversion element 8A and the magnetoelectric conversion element 8B are placed opposite each other across a gap 2A of the through-slit 2, and are configured in positions such that they are located within a dimension line of the width length W1 or the width length W2 in the X-direction, within a dimension line of the height dimension W3 in the Y-direction, and within a dimension line of the thickness dimension W4 in the Z-direction, and the magnetically-sensitive axis is in the X-direction.

Moreover, the current sensor 100 has a resin housing which is not illustrated in the drawing, and a printed circuit board which is not illustrated in the drawing and where a magnetic detection means which is not illustrated in the drawing and a connector which is not illustrated in the drawing are mounted; and the printed circuit board, the conductor 1, the magnetic core 5, and the magnetic core 6 are fixed to the resin housing and the magnetoelectric conversion elements 8A, 8B are configured inside the magnetic detection means.

The magnetic detection means has a differential calculation unit, which is not illustrated in the drawing, that amplifies output signals, which are respectively output from the magnetoelectric conversion element 8A and the magnetoelectric conversion element 8B according to the magnetic flux density amount detected by the magnetoelectric conversion element 8A and the magnetoelectric conversion element 8B, performs differential calculation of the two amplified output signals, and outputs differential calculation values; and the differential calculation values are output via the connector outside the current sensor 100.

The conductor 1 is a nonmagnetic material such as a copper material or an aluminum material, is formed of a single material or a plurality of materials, and has a rectangular cross-section of a flat plate shape.

The through-slit 2 is located at the center of the X-directional width dimension of the conductor 1 in this embodiment and the current path 3 and the current path 4 have the same cross-sectional area (an XY plane). A part of the current path 3 constitutes a sidewall on one side of the through-slit 2 and a part of the current path 4 constitutes a sidewall on the other side of the through-slit 2.

The magnetic core 5 and the magnetic core 6 are laminated cores, rolled cores, or cast cores which are formed of a single magnetic material or a plurality of magnetic materials, wherein the magnetic materials are, for example, a silicon steel plate, ferrite, and permalloy; and in this embodiment, two magnetic cores of the same shape (U-shaped sectional shape), each of which is formed of a single magnetic substance, are placed in positions with their end faces facing opposite each other.

The magnetoelectric conversion element 8A and the magnetoelectric conversion element 8B have the magnetically-sensitive axis of the same polarity in the X-direction and detect magnetic flux density components in the X-direction of magnetic fluxes generated by the electric current to be detected which flows through the conductor 1.

Moreover, the magnetoelectric conversion element 8A and the magnetoelectric conversion element 8B are configured as two detection elements in this embodiment; however, two magnetic sensors such as ICs, each of which has one detection element, may be used or one magnetic sensor having two detection elements may be used. The detection elements may be of any type as long as it is, for example, Hall effect elements or magnetoresistive elements capable of detecting the magnetic fluxes and performing outputs; and preferably, if one magnetic sensor having two detection elements is used, the number of components of the current sensor can be reduced as compared to the case of using two magnetic sensors and a cost advantage also arises.

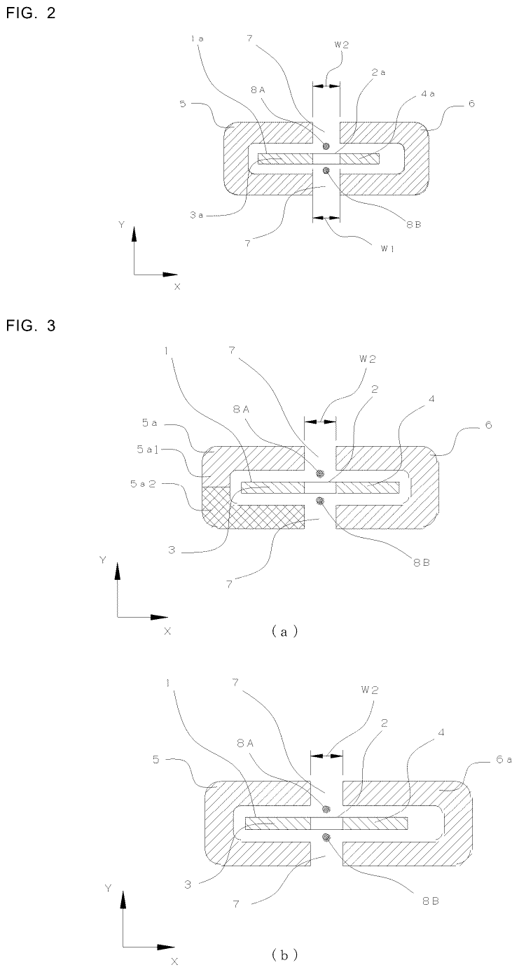

FIGS. 2 and 3 illustrate conductors and magnetic cores of different shapes as diagrams corresponding to sectional views taken along the line A-A in FIG. 1(b). FIG. 2 is a diagram illustrating a configuration example in which the position of the through-slit 2 of the current sensor 100 illustrated in FIG. 1 and cross-sectional areas of the current path 3 and the current path 4 are changed; and FIG. 3 is diagrams illustrating configuration examples in which the magnetic core 5 and the magnetic core 6 of the current sensor 100 illustrated in FIG. 1 are changed.

In this embodiment, the through-slit 2 is located at the center of the X-directional width dimension of the conductor 1 and the current path 3 and the current path 4 have the same cross-sectional area (the XY plane); however, without limitation to the above, as illustrated in FIG. 2, a through-slit 2a does not have to be located at the center of the X-directional width dimension of a conductor 1a and a current path 3a and a current path 4a may have unidentical cross-sectional areas.

Moreover, regarding the magnetic core 5 and the magnetic core 6 in this embodiment, two magnetic cores, each of which is formed of a single magnetic substance and has the same shape (U-shaped sectional shape), are placed to face opposite each other; however, without limitation to the above, as illustrated in FIG. 3(a), a U-shaped magnetic core which is formed of a plurality of magnetic substances may be used so that a magnetic core 5a is formed of a magnetic substance 5a1 and a magnetic substance 5a2. Also, as illustrated in FIG. 3(b), the magnetic core 5 and the magnetic core 6 do not have to have the same shape and, for example, the magnetic core 6 may be a magnetic core 6a which is long in the X-direction. In addition, the magnetic core may have a protrusion and/or a recess as long as it has a substantially U-shaped part which is a shape to surround the periphery of each current path excluding the through-slit 2. The shapes and configurations of the magnetic cores illustrated in FIG. 3 are shape examples in this embodiment and do not limit the configuration of the present invention.

Regarding the current sensor 100 according to Embodiment 1 configured as described above, when the electric current to be detected is applied to the conductor 1, the electric current is divided into and passes through the current path 3 and the current path 4. Under this circumstance, the total amount of the electric current which passes through the current path 3 and the current path 4 is equal to the amount of the electric current to be detected in the conductor 1.

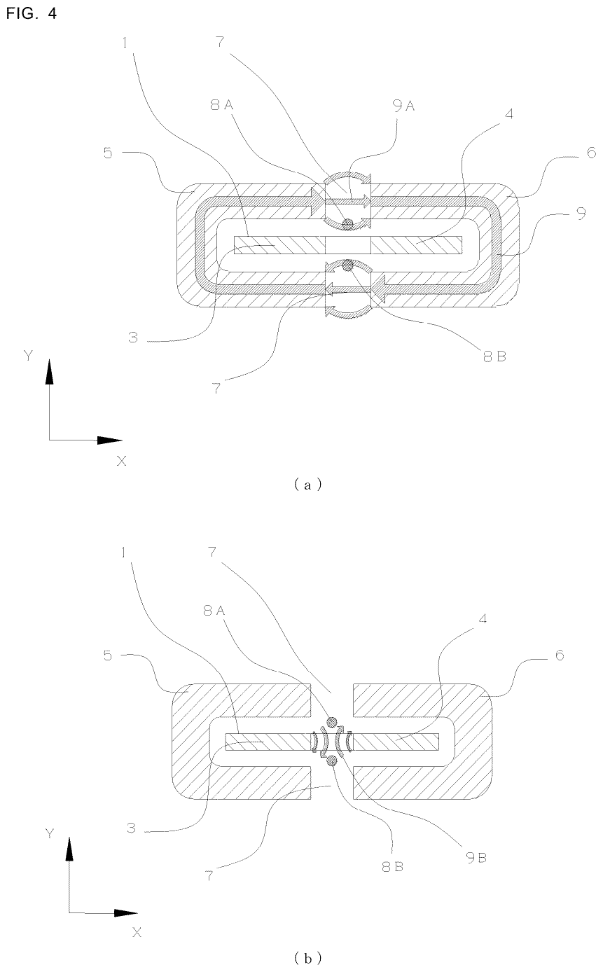

Now, an explanation will be provided about magnetic fluxes generated by the electric current which flows through the current path 3 and the current path 4. FIG. 4 is schematic views of magnetic flux paths as sectional views taken along the line A-A in FIG. 1(b) when the electric current to be detected is applied to the current sensor 100; FIG. 4(a) is a diagram illustrating magnetic flux paths which pass through the magnetic core 5, the magnetic core 6, and the core gaps 7; and FIG. 4(b) is a diagram illustrating magnetic flux paths whose magnetism does not converge at the magnetic core 5 or the magnetic core 6.

When a direct current in the positive Z-direction is applied, as the electric current to be detected, to the conductor 1, magnetic fluxes are generated from each current path according to the amount of electric current which is divided into and flows through the current path 3 and the current path 4 as illustrated in FIG. 4(a); and since the magnetic core 5 and the magnetic core 6 are located to surround the periphery of the current path 3 and the current path 4, the magnetic fluxes generated from the electric currents flowing through the respective current paths are combined and their magnetism converges at the magnetic core 5 and the magnetic core 6, so most of the generated magnetic fluxes pass through inside the magnetic core 5 and the magnetic core 6 in directions indicated with arrows like a magnetic flux path 9. Under this circumstance, a magnetic flux path in the core gap 7 forms a magnetic flux path like a magnetic flux 9A.

Moreover, regarding the magnetic fluxes generated from the electric currents flowing through the current path 3 and the current path 4, there are also magnetic fluxes whose magnetism do not converge at the magnetic core 5 or the magnetic core 6, and a magnetic flux 9B also exists as illustrated in FIG. 4(b).

The magnetoelectric conversion element 8A and the magnetoelectric conversion element 8B detect the magnetic fluxes of the magnetic flux 9A and the magnetic flux 9B by combining them together. The signals output from the magnetoelectric conversion element 8A and the magnetoelectric conversion element 8B according to the detected magnetic flux density amount become subject to the differential calculation by a differential calculation unit, which is not illustrated in the drawing, and are then output to the outside via a connector which is not illustrated in the drawing.

Particularly, regarding the magnetic flux 9A, most of the magnetic fluxes generated from the electric currents flowing through the current path 3 and the current path 4 are combined and their magnetism converged by the magnetic core 5 and the magnetic core 6, so its magnetic flux density is large; and as compared to the magnetic fluxes generated only from the conductor 1 when the magnetic core 5 and the magnetic core 6 are excluded as in the conventional technology, the magnetoelectric conversion element 8A and the magnetoelectric conversion element 8B can detect a very large magnetic flux density amount and can detect the sum total amount of the electric currents flowing through the current path 3 and the current path 4 based on the large magnetic flux density amount.

In FIG. 4(a), the magnetic flux 9A in the upper part of the drawing is a magnetic flux in the X positive direction and the magnetic flux 9A in the lower part of the drawing is a magnetic flux in the opposite direction, that is, the X negative direction; and the magnetoelectric conversion element 8A and the magnetoelectric conversion element 8B are located in positions such that the magnetically-sensitive axis is in the X-direction and the magnetically sensitive polarity is positive in the X positive direction, so that when performing the differential calculation of the outputs from the magnetoelectric conversion element 8A and the magnetoelectric conversion element 8B, both the outputs are added together and the doubled magnetic flux density amount can be detected. Accordingly, it is possible to reduce the amplification factor for the output signals; and even if a very small magnetic flux density amount occurs after cancellation by the differential calculation under the external magnetic field environment of the current sensor, it is possible to make it less susceptible.

On the other hand, regarding an external magnetic field having a magnetic flux source outside the magnetic core 5 and the magnetic core 6, major magnetic fluxes for the magnetoelectric conversion element 8A and the magnetoelectric conversion element 8B, which are close to each other, are those in the same direction and with the same polarity and the outputs from the magnetoelectric conversion element 8A and the magnetoelectric conversion element 8B are offset by performing the differential calculation and the differential calculation outputs become small. Furthermore, the magnetic core 5 and the magnetic core 6 serve as shields and their outputs become extremely small, thereby making it possible to suppress the influence of the external magnetic field.

Moreover, if a high-frequency alternating current component is included in the electric current to be detected, the current sensor according to the present invention can adjust changes in the magnetic flux density amount caused by the skin effect by adjusting the arrangement of the magnetoelectric conversion elements 8A, 8B, the width dimension W1 of the through-slit 2, and the width dimension W2 of the core gap 7, respectively. (For example, an electric current of a motor drive inverter circuit includes many high-frequency alternating current components; and with a conventional current sensor, the electric current intensively converges on the surface of the conductor due to the skin effect, thereby causing changes in a magnetic flux distribution and also causing changes in the magnetic flux density amount detected by the magnetoelectric conversion elements according to the height of the included frequency.)

Now, an explanation will be provided about the influence of the high-frequency alternating current included in the electric current to be detected. If the electric current to be detected includes a high-frequency alternating current of, for example, approximately 1000 Hz or higher, the current density of the electric current which flows through the current path 3 and the current path 4 according to that frequency converges at both ends of each current path in the X positive direction and the X negative direction due to the skin effect and the magnetic flux distribution similarly changes accordingly; however, since the magnetic core 5 and the magnetic core 6 are located to surround the periphery of the current path 3 and the current path 4, the magnetism of the magnetic fluxes generated from the electric currents flowing through the current paths converges at the magnetic core 5 and the magnetic core 6 and most of the generated magnetic fluxes forms the magnetic flux path 9 in the same manner as in a case where the electric current to be detected is a direct current.

Moreover, magnetic fluxes which do not converge at the magnetic core 5 or the magnetic core 6 also exist in the magnetic fluxes generated from the electric currents flowing through the current path 3 and the current path 4; and the magnetic flux 9B also exists in the same manner as in the case of applying the direct current.

However, when the high-frequency alternating current is applied, iron losses which occur at the magnetic core 5 and the magnetic core 6 become large. So, as compared to the case where the direct current is applied, the magnetic flux 9A attenuates; and contrarily, the electric currents which flow through the current path 3 and the current path 4 converge at both their ends in the X-direction of the respective current paths due to the influence of the skin effect, so that the magnetic flux 9B increases due to the influence of the electric currents which have converged on the through-slit 2 side.

Under this circumstance, when the arrangement of the through-slit 2, the core gaps 7, the magnetoelectric conversion element 8A, and the magnetoelectric conversion element 8B is changed and the status of the magnetic flux distribution by the skin effect is changed, the magnetic flux density amount of the magnetic flux 9A and the magnetic flux 9B detected by the magnetoelectric conversion element 8A and the magnetoelectric conversion element 8B can be adjusted arbitrarily and it also becomes possible to, for example, offset a changed amount of the combined magnetic flux density amount against the decreasing magnetic flux 9A and the increasing magnetic flux 9B and, contrarily, to increase or decrease the changed amount.

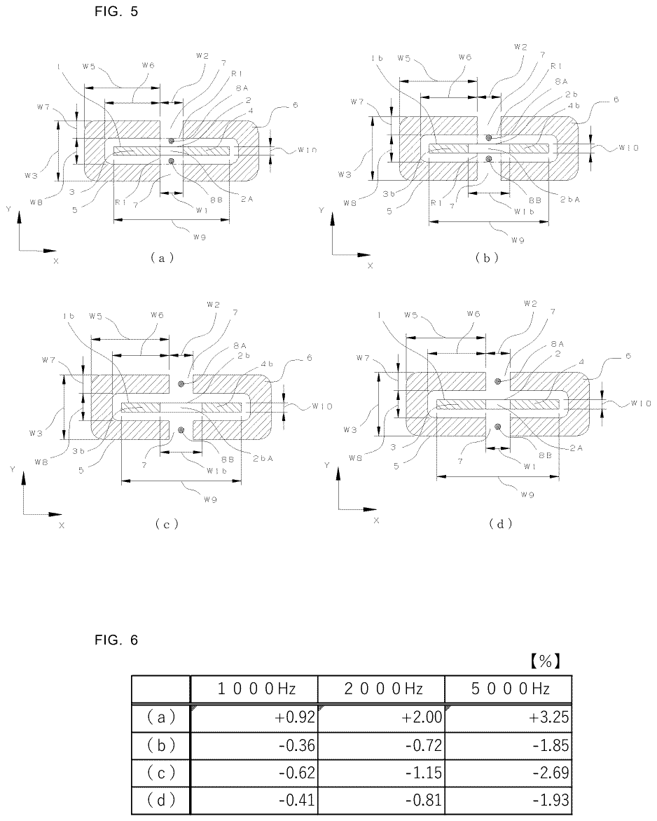

Now, an explanation will be provided about changes in the magnetic flux density amount of the magnetic flux 9A and the magnetic flux 9B in representative configuration examples by using a simulation. FIG. 5 illustrates, as diagrams corresponding to sectional views taken along the line A-A in FIG. 1(b), configuration examples of the arrangement of the through-slit 2, the core gaps 7, the magnetoelectric conversion element 8A, and the magnetoelectric conversion element 8B in this embodiment; and FIG. 5(a) is a diagram illustrating a configuration example (a) that is the configuration where the width length W1 and the width length W2 are of the same dimension and these two width lengths completely overlap with each other when viewed from the Y-direction and the magnetoelectric conversion element 8A and the magnetoelectric conversion element 8B are located in an arrangement area R1 (the arrangement area R1 will be described later); FIG. 5(b) is a diagram illustrating a configuration example (b) that is the configuration where a width length W1b of a conductor 1b is larger than the width length W2 and the width length W2 overlaps with and is included in the width length W1b as viewed from the Y-direction and the magnetoelectric conversion element 8A and the magnetoelectric conversion element 8B are located in the arrangement area R1; FIG. 5(c) is a diagram illustrating a configuration example (c) that is the configuration where the width length W1b of the conductor 1b is larger than the width length W2 and the width length W2 overlaps with the range of the width length W1b as viewed from the Y-direction and the magnetoelectric conversion element 8A and the magnetoelectric conversion element 8B are located within the core gap 7; and FIG. 5(d) is a diagram illustrating a configuration example (d) that is the configuration where the width length W1 and the width length W2 are of the same dimension and these two width lengths completely overlap with each other as viewed from the Y-direction and the magnetoelectric conversion element 8A and the magnetoelectric conversion element 8B are located within the core gap 7. Moreover, the arrangement area R1 is, as illustrated in FIG. 5(a) and FIG. 5(b), within the range inside the dimension line of an inside height dimension W8 of the magnetic cores 5, 6 in the Y-direction, inside the dimension line of the width length W2 of the core gap 7, inside the dimension line of the thickness dimension W4 (see FIG. 1(b)), and outside the gap 2A of the through-slit 2.

FIG. 6 is a table showing simulation results of the magnetic flux density change rate at frequencies of 1000 Hz, 2000 Hz, and 5000 Hz, which is detected by the magnetoelectric conversion element 8A and the magnetoelectric conversion element 8B at the above-mentioned respective frequencies with respect to the direct current in the configuration examples (a) to (d) illustrated in FIG. 5.

This simulation was performed by using finite element method electromagnetic field analysis software; the applied electric current was set as 500 A, and the magnetic flux density amount in the X positive direction at placement points of the magnetoelectric conversion element 8A and the magnetoelectric conversion element 8B was simulated under conditions of the direct current and alternating currents at the frequencies of 1000 Hz, 2000 Hz, and 5000 Hz; and after that, the magnetic flux density amount of the difference between them was calculated; the result under the direct current condition was used as the basis and was compared with the results under the alternating current conditions of the respective frequencies; and the magnetic flux density change rate indicating a rate of changes in the magnetic flux density amount was calculated.

Moreover, regarding the magnetic core 5 and the magnetic core 6 in this simulation as illustrated in FIG. 5, the outside height dimension W3 in the Y-direction is 10.5 mm, an outside dimension W5 in the X-direction is 13.0 mm, an inside dimension W6 in the X-direction is 9.5 mm, an inside-outside dimension W7 in the Y-direction is 3.0 mm, the inside dimension W8 in the Y-direction is 4.5 mm; the width length W2 of the core gap 7 is 4.0 mm; a magnetic core (the thickness dimension W4 in the Z-direction is 3.0 mm; see FIG. 1(b)) which is configured by stacking six U-shaped nondirectional silicon steel plates, each of which is 0.5 mm thick, one over another in the Z-direction is used; contact positions when the U-shaped nondirectional silicon steel plates are stacked together are insulation settings; regarding the conductor 1, 1b, an outside dimension W9 in the X-direction is 20.0 mm, a Y-directional dimension W10 is 1.5 mm, the width length W1 of the through-slit 2 of the conductor 1 is 4.0 mm, the width length W1b of the through-slit 2b of the conductor 1b is 7.0 mm; the magnetoelectric conversion elements 8A, 8B are located symmetrically with respect to the centerline of the dimension W10; and the simulation was performed in the configuration examples (a)(b) with the arrangement where the magnetoelectric conversion elements 8A, 8B are located on the center lines of the width length W2 of the core gap 7 and the thickness dimension W4 (see FIG. 1(b)) and the distance between the magnetoelectric conversion elements 8A, 8B is 2.6 mm, and in the configuration examples (c)(d) with the arrangement that the magnetoelectric conversion elements 8A, 8B are located on the center lines of the width length W2 of the core gap 7 and the thickness dimension W4 (see FIG. 1(b)) and the distance between the magnetoelectric conversion elements is 7.5 mm.

In the configuration example (a), as illustrated in FIG. 5(a), the magnetoelectric conversion element 8A and the magnetoelectric conversion element 8B are close to the end faces of the current path 3 and the current path 4 of the conductor 1 on the through-slit 2 side, so the skin effect causes the electric currents to come closer to the magnetoelectric conversion elements 8A, 8B, thereby increasing the magnetic flux 9B (see FIG. 4); and consequently, an increase amount of the magnetic flux 9B becomes larger than a decrease amount of the magnetic flux 9A (see FIG. 4) due to the attenuation by iron losses of the magnetic cores 5, 6, so that the combined and detected magnetic flux density amount of the magnetoelectric conversion element 8A and the magnetoelectric conversion element 8B increases more than the case of the application of the direct current. Therefore, as illustrated in FIG. 6, the magnetic flux density change rate regarding which the magnetic flux density amount is compared to the case of the application of the direct current is +3.25% upon the application of the 5000 Hz alternating current.

In the configuration example (b), as illustrated in FIG. 5(b), the magnetoelectric conversion element 8A and the magnetoelectric conversion element 8B are far from the end faces of the current path 3b and the current path 4b of the conductor 1b on the through-slit 2b side, so the distance between the electric currents flowing through the current path 3b and the current path 4b becomes longer, thereby suppressing the increase of the magnetic flux 9B (see FIG. 4) due to the skin effect and making the attenuation of the magnetic flux 9A (see FIG. 4) due to the iron losses of the magnetic cores 5, 6 more dominant. Consequently, as illustrated in FIG. 6, the magnetic flux density change rate regarding which the magnetic flux density amount is compared to when applying the direct current is −1.85% upon the application of the 5000 Hz alternating current.

In the configuration example (c), as illustrated in FIG. 5(c), the magnetoelectric conversion element 8A and the magnetoelectric conversion element 8B are located in the area inside the relevant core gap 7 and are much farther from the end faces of the current path 3b and the current path 4b of the conductor 1b on the through-slit 2b side than in the configuration example (b), thereby further suppressing the increase of the magnetic flux 9B (see FIG. 4) due to the skin effect and making the attenuation of the magnetic flux 9A (see FIG. 4) due to the iron losses of the magnetic cores 5, 6 further more dominant. Consequently, as illustrated in FIG. 6, the magnetic flux density change rate regarding which the magnetic flux density amount is compared to when applying the direct current is −2.69% upon the application of the 5000 Hz alternating current, so that the magnetic flux density change rate is larger than that of the configuration example (b).

In the configuration example (d), as illustrated in FIG. 5(d), the magnetoelectric conversion element 8A and the magnetoelectric conversion element 8B are located in the area inside the relevant core gap 7 in the same manner as in the configuration example (c), but are closer to the end faces of the current path 3 and the current path 4 of the conductor 1 on the through-slit 2 side as compared to the configuration example (c), so that the suppression on the increase of the magnetic flux 9B (see FIG. 4) due to the skin effect is alleviated. Therefore, as illustrated in FIG. 6, the magnetic flux density change rate regarding which the magnetic flux density amount is compared to when applying the direct current is −1.93% upon the application of the 5000 Hz alternating current, so that the magnetic flux density change rate is smaller than that of the configuration example (c).

As in the configuration examples (a) to (d), the change amount of the magnetic flux density when applying the alternating current can be adjusted by changing the arrangement of the through-slit 2, the core gaps 7, the magnetoelectric conversion element 8A, and the magnetoelectric conversion element 8B and it is possible to suppress or promote the change amount of the magnetic flux density amount.

Regarding the configuration examples (a)(b), the positive and the negative of the magnetic flux density change rate are reversed and the changes in the detected magnetic flux density amount according to the frequency of the electric current to be detected can be suppressed and minimized by optimizing the configuration of the width length W1, W1b and the width length W2. Also, regarding the configuration examples (c)(d), the attenuation of the magnetic flux 9A caused by the iron losses of the magnetic cores can be suppressed by making the width length W1, W1b closer to the width length W2, and such changes can be suppressed and minimized by making the width length W1, W1b equal to or less than the width length W2.

As a result, it becomes possible to design appropriate frequency characteristics in the electric current detection characteristics by adjusting the arrangement of the through-slit 2, the core gaps 7, and the magnetoelectric conversion elements 8A, 8B for each design in consideration of the attenuation of the magnetic flux 9A due to the iron losses of the magnetic cores and the increase of the magnetic flux 9B due to the skin effect.

Moreover, in both the configuration examples (c)(d), the detected magnetic flux density amount when applying the high-frequency alternating current is negative as compared to when applying the direct current; however, as the magnetoelectric conversion element 8A, 8B is located within the core gap 7, the magnetic flux density amount which can be detected from the magnetic flux 9A is large and it is possible to detect the magnetic flux density amount which is larger than that of the configuration examples (a)(b). Therefore, in the configuration examples (c)(d) rather than in the configuration examples (a)(b), it becomes possible to reduce the amplification factor for the output signal(s) which is output when the magnetic flux density amount is detected; and it is possible to suppress the influence more on the changes of the magnetic fluxes, for example, under the external magnetic field environment.

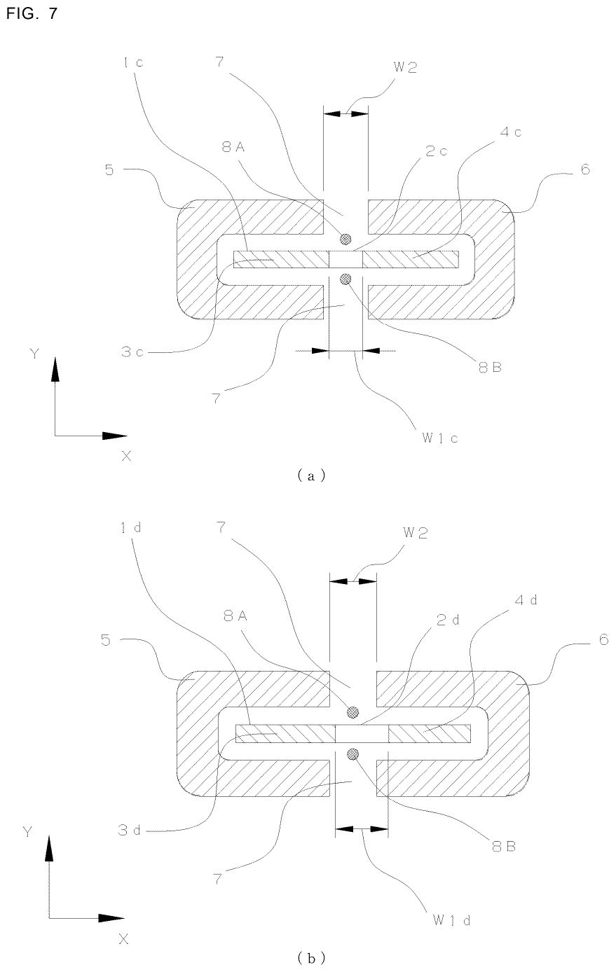

Now, an explanation will be provided about the configuration of the width length W1 of the through-slit 2 and the width length W2 of the core gap 7. FIG. 7 shows, as diagrams corresponding to sectional views taken along the line A-A in FIG. 1(b), configuration examples of the through-slit 2 and the core gap 7; and FIG. 7(a) is the configuration where a width length W1c is a dimension smaller than the width length W2 and the width length W1c overlaps with the range of the width length W2 as viewed from the Y-direction; and FIG. 7(b) shows the configuration where a width length W1d and the width length W2 are of different dimensions and the width length W1d and the width length W2 partly overlap with each other as viewed from the Y-direction. Moreover, FIG. 7(a) and 7(b) show the configuration examples of the width lengths W1c, W1d and the width length W2 and no particular reference is made to the arrangement of the magnetoelectric conversion elements 8A, 8B.

The configuration examples (a) to (d) illustrated in FIG. 5(a) to FIG. 5(d) are configured so that the width length W1, W1b is of a dimension equal to or longer than the width length W2; however, without limitation to the above, as illustrated in FIG. 7(a), the width length W1c may be equal to or shorter than the dimension of the width length W2. Also, in FIG. 5(a) to 5(d), the configuration is set such that the through-slit 2, 2b and the core gaps 7 are located symmetrical with respect to the center line of the X-directional width of the conductor 1, 1b; however, without limitation to the above, as illustrated in FIG. 7(b), it is possible to adjust the magnetic flux density amount combined and detected by the magnetoelectric conversion element 8A and the magnetoelectric conversion element 8B as long as the configuration is set such as the width length W1d and the width length W2 partly overlap with each other as viewed from the Y-direction. Incidentally, FIG. 7(a) and 7(b), just like FIG. 5(a) and 5(b), show the examples of the width length W1c, W1d of the through-slit 2c, 2d and the width length W2 of the core gap 7 where the magnetoelectric conversion element 8A and the magnetoelectric conversion element 8B are located within the aforementioned arrangement area R1; however, in the same manner as in FIG. 5(c) and 5(d), the above examples can be also applied to the case where each of the magnetoelectric conversion element 8A and the magnetoelectric conversion element 8B is located within the relevant core gap 7.

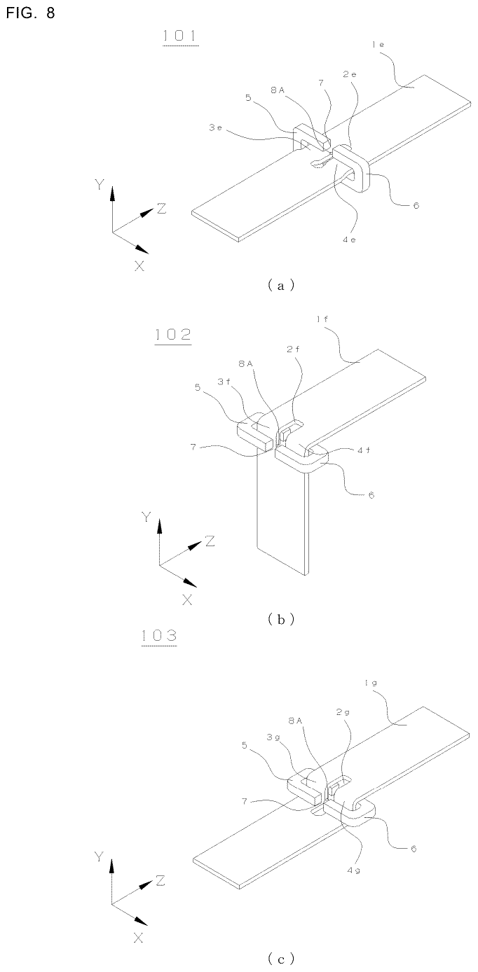

Now, an explanation will be provided about different aspects of the conductor 1. FIG. 8 is perspective views of a current sensor having a conductor with different aspects from those of the conductor 1 in this embodiment. Referring to FIG. 8(a), a conductor 1e of a current sensor 101 can adjust the frequency characteristics in a high frequency range in the same manner even if a current path 3e and a current path 4e are not configured on the same plane.

Moreover, as illustrated in FIG. 8(b) and 8(c), a current sensor 102, 103 is designed to have a conductor 1f, 1g which is bent (90-degree bent) at a portion including each through-slit 2f, 2g; and the conductor may be of a shape which is bent once like the conductor 1f or may be of a shape which is bent a plurality of times (for example, twice) like the conductor 1g; and as the bending makes the conductor 1f, 1g come closer to the magnetic cores 5, 6, the magnetic fluxes whose magnetism is converged by the magnetic cores 5, 6 increase, so that the magnetic flux 9A (see FIG. 4) increases, the magnetic flux density amount detected by the magnetoelectric conversion elements 8A, 8B increases, and it is possible to reduce the amplification factor for the output signals which are output from the magnetoelectric conversion elements 8A, 8B. Moreover, particularly in the configuration example in FIG. 8(c), when the Y-directional outside dimension of the magnetic core 5, 6 is smaller than the Z-directional outside dimension, it is possible to set a lower height as compared to the configuration of FIG. 1(a) in this embodiment or the configuration example in FIG. 8(a).

The following operations and advantages are obtained according to one embodiment of the present invention which has been explained above.

(1) The current sensor 100 to 103 includes: the conductor 1, 1a to 1g to which the electric current to be detected is applied, and which has the current path 3, 3a to 3g and the current path 4, 4a to 4g that branch at the through-slit 2, 2a to 2g; the magnetic core 5, 5a and the magnetic core 6, 6a, each of which is of a substantially U-shape and has two end faces; and a pair of magnetoelectric conversion elements 8A, 8B that are placed opposite each other across the through-slit 2, 2a to 2g, respectively detect magnetic flux density in a specified direction of a magnetically-sensitive axis of magnetic fluxes generated from the electric current to be detected, and output an output signal according to the magnetic flux density. The magnetic core 5, 5a is placed along the periphery of the current path 3, 3a to 3g to surround at least a part of the periphery excluding a portion which forms a sidewall on one side of the through-slit 2, 2a to 2g; and the magnetic core 6, 6a is placed along the periphery of the current path 4, 4a to 4g to surround at least a part of the periphery excluding a portion which forms a sidewall on the other side of the through-slit 2, 2a to 2g. Each of the magnetic core 5, 5a and the magnetic core 6, 6a is placed in a position with their two end faces facing opposite each other, and the core gap 7 is formed between the two opposed end faces. Consequently, it is possible to provide the current sensor 100 to 103 capable of increasing the magnetic flux density detected by the magnetoelectric conversion elements 8A, 8B and reducing the amplification factor for the output signals which are output from the magnetoelectric conversion elements 8A, 8B.

(2) The through-slit 2, 2a to 2g and the core gaps 7 are formed so that they at least partly overlap with each other in the width direction (the X-direction) of the conductor 1, 1a to 1g as viewed from the penetration direction (the Y-direction) of the through-slit 2, 2a to 2g. Consequently, it is possible to increase and appropriately adjust the magnetic flux density detected by the magnetoelectric conversion elements 8A, 8B by arbitrarily adjusting the arrangement of the pair of magnetoelectric conversion elements 8A, 8B and the direction of the magnetically-sensitive axis, the width dimension W1, W1b to W1d of the through-slit 2, 2a to 2g, and the width dimension W2 of the core gap 7, respectively.

(3) For example, as illustrated in FIG. 5(a) and 5(b), the pair of magnetoelectric conversion elements 8A, 8B may be placed in the arrangement area R1 sectioned by the inside height dimension W8 and the thickness dimension W4 of the magnetic core 5 and the magnetic core 6 and the width dimension W2 of the core gap 7 and may have the magnetically-sensitive axis in the direction (X-direction) which is horizontal to the width direction of the conductor 1, 1b. Under this circumstance, as illustrated in FIG. 5(a) and FIG. 7(a), the width dimension W1, W1c of the through-slit 2, 2c may be equal to or shorter than the width dimension W2 of the core gap 7; and as illustrated in FIG. 5(b), the width dimension W1b of the through-slit 2b may be longer than the width dimension W2 of the core gap 7. Moreover, as illustrated in FIG. 5(c) and 5(d), the pair of magnetoelectric conversion elements 8A, 8B may be located within the relevant core gap 7 and may have the magnetically-sensitive axis in the direction (X-direction) which is horizontal to the width direction of the conductor 1, 1b. Under this circumstance, as illustrated in FIG. 5(c), the width dimension W1b of the through-slit 2b may be longer than the width dimension W2 of the core gap 7; and as illustrated in FIG. 5(d) and FIG. 7(a), the width dimension W1, W1c of the through-slit 2, 2c may be equal to or shorter than the width dimension W2 of the core gap 7. Consequently, when the electric current to be detected including the high-frequency alternating current is applied, it is possible to adjust the magnetic flux density, which is detected by the magnetoelectric conversion elements 8A, 8B, to become a desired value by adjusting the arrangement of the pair of magnetoelectric conversion elements 8A, 8B and the direction of the magnetically-sensitive axis, the width dimension W1, W1c of the through-slit 2, 2c, and the width dimension W2 of the core gap 7.

With the present invention as described above, it is possible to appropriately adjust the magnetic flux density detected by the magnetoelectric conversion elements 8A, 8B and arbitrarily adjust the frequency characteristics upon the application of the alternating current by adjusting the arrangement of the pair of magnetoelectric conversion elements 8A, 8B and the direction of the magnetically-sensitive axis, the width dimension W1, W1b to W1d of the through-slit 2, 2a to 2g, and the width dimension W2 of the core gap 7, respectively. Therefore, the current sensor 100 to 103 which is capable of stably detecting the electric current also when applying the alternating current can be provided without the problems which the conventional current sensors have.

(4) The conductor 1f, 1g has the shape which is bent once or more in its portion including the through-slit 2f, 2g. Consequently, it is possible to make the current sensor 102, 103 have a lower height.

Incidentally, the present invention is not limited to the above-described embodiments or variations. For example, the current path 3, 3a to 3g and the current path 4, 4a to 4g which branch at the through-slit 2, 2a to 2g do not have to be of flat plate shapes as illustrated in FIG. 1 to FIG. 8, but may have other shapes such as a cylindrical shape. Moreover, two or more pairs of magnetic cores 5, 6 and magnetoelectric conversion elements 8A, 8B may be placed with respect to one through-slit 2, 2a to 2g, or the through-slit 2, 2a to 2g may be formed at two or more locations in the conductor 1, 1a to 1g. Unless the features of the present invention are impaired, other forms which can be thought of within the scope of the technical idea of the present invention are also included within the scope of the present invention. Also, a configuration obtained by combing the aforementioned plurality of embodiments may be employed.

### REFERENCE SIGNS LIST

1: conductor
1a: conductor
1b: conductor
1c: conductor
1d: conductor
1e: conductor
1f: conductor
1g: conductor
2: through-slit
2a: through-slit
2b: through-slit
2c: through-slit
2d: through-slit
2e: through-slit
2f: through-slit
2g: through-slit
2A: gap part
2bA: gap part
3: current path
3a: current path
3b: current path
3c: current path
3d: current path
3e: current path
3f: current path
3g: current path
4: current path
4a: current path
4b: current path
4c: current path
4d: current path
4e: current path
4f: current path
4g: current path
5: magnetic core
5a: magnetic core
5a1: magnetic core
5a2: magnetic core
6: magnetic core
6a: magnetic core
7: core gap
8A: magnetoelectric conversion element
8B: magnetoelectric conversion element
9: magnetic flux path
9A: magnetic flux
9B: magnetic flux
W1: width length
W1b: width length
W1c: width length
W1d: width length
W2: width length
W3: height dimension
W4: thickness dimension
W5: outside dimension
W6: inside dimension
W7: inside-outside dimension
W8: inside height dimension
W9: outside dimension
W10: dimension
R1: arrangement area

1.-2. (canceled)

3. A current sensor comprising:
a conductor to which an electric current to be detected is applied, and which has a first current path and a second current path that branch at a through-slit;
substantially U-shaped first and second magnetic cores, each of which has two end faces; and
a pair of magnetoelectric conversion elements that are placed opposite each other across the through-slit, respectively detect magnetic flux density in a specified direction of a magnetically-sensitive axis of a magnetic flux generated from the electric current to be detected, and output an output signal according to the magnetic flux density,
wherein the first magnetic core is placed to surround at least a part of a periphery of the first current path excluding a portion which forms a sidewall on one side of the through-slit;
wherein the second magnetic core is placed to surround at least a part of a periphery of the second current path excluding a portion which forms a sidewall on the other side of the through-slit;
wherein each of the first and second magnetic cores is placed in a position with their two end faces facing opposite each other;
wherein a core gap is formed between the two opposed end faces; and
wherein the pair of magnetoelectric conversion elements are placed in an arrangement area sectioned by an inside height dimension and a thickness dimension of the first and second magnetic cores and a width dimension of the core gap and have the magnetically-sensitive axis in a direction horizontal to a width direction of the conductor.

4. The current sensor according to claim 3,
wherein a width dimension of the through-slit is equal to or shorter than the width dimension of the core gap.

5. The current sensor according to claim 3,
wherein a width dimension of the through-slit is longer than the width dimension of the core gap.

6. A current sensor comprising:
a conductor to which an electric current to be detected is applied, and which has a first current path and a second current path that branch at a through-slit;
substantially U-shaped first and second magnetic cores, each of which has two end faces; and
a pair of magnetoelectric conversion elements that are placed opposite each other across the through-slit, respectively detect magnetic flux density in a specified direction of a magnetically-sensitive axis of a magnetic flux generated from the electric current to be detected, and output an output signal according to the magnetic flux density,
wherein the first magnetic core is placed to surround at least a part of a periphery of the first current path excluding a portion which forms a sidewall on one side of the through-slit;
wherein the second magnetic core is placed to surround at least a part of a periphery of the second current path excluding a portion which forms a sidewall on the other side of the through-slit;
wherein each of the first and second magnetic cores is placed in a position with their two end faces facing opposite each other:
wherein a core gap is formed between the two opposed end faces; and
wherein the pair of magnetoelectric conversion elements are placed within the core gap and have the magnetically-sensitive axis in a direction horizontal to a width direction of the conductor.

7. The current sensor according to claim 6,
wherein a width dimension of the through-slit is longer than a width dimension of the core gap.

8. The current sensor according to claim 6,
wherein a width dimension of the through-slit is equal to or shorter than a width dimension of the core gap.

9. The current sensor according to claim 3,
wherein a part of the conductor including the through-slit has a shape which is bent once or more.

10. The current sensor according to claim 6,
wherein a part of the conductor including the through-slit has a shape which is bent once or more.

11. The current sensor according to claim 3,
wherein the through-slit and the core gap are formed so that they at least partly overlap with each other in a width direction of the conductor as viewed from a penetration direction of the through-slit.

12. The current sensor according to claim 6,
wherein the through-slit and the core gap are formed so that they at least partly overlap with each other in a width direction of the conductor as viewed from a penetration direction of the through-slit.
